(19) United States
(12) Patent Application Publication
(10) Pub. No.: US 2015/0144994 A1
(43) Pub. Date: May 28, 2015

(54) POWER SEMICONDUCTOR DEVICE

(71) Applicant: SAMSUNG ELECTRO-MECHANICS CO., LTD., Suwon (KR)

(72) Inventors: Jae Kyu SUNG, Suwon (KR); Dong Soo SEO, Suwon (KR); Chang Su Jang, Suwon (KR); Jae Hoon PARK, Suwon (KR); In Hyuk SONG, Suwon (KR)

(73) Assignee: SAMSUNG ELECTRO-MECHANICS CO., LTD., Suwon (KR)

(21) Appl. No.: 14/329,378

(22) Filed: Jul. 11, 2014

(30) Foreign Application Priority Data
Nov. 27, 2013 (KR) 10-2013-0145005

(51) Int. Cl. H01L 29/739; H01L 29/417

(52) U.S. Cl. CPC H01L 29/7393; H01L 29/417
USPC 257/139

(57) ABSTRACT

A power semiconductor device may include: a first semiconductor layer having a first conductivity type; a second semiconductor layer formed on the first semiconductor layer, having a concentration of impurities higher than that of the first semiconductor layer, and having the first conductivity type; a third semiconductor layer formed on the second semiconductor layer and having a second conductivity type; a fourth semiconductor layer formed in an upper surface of the third semiconductor layer and having the first conductivity type; and trench gates penetrating from the fourth semiconductor layer into a portion of the first semiconductor layer and having gate insulating layers formed on surfaces thereof. The trench gates have a first gate, a second gate, and a third gate are sequentially disposed from a lower portion thereof, and the first gate, the second gate, and the third gate are insulated from each other by gate insulating films.

### CROSS-REFERENCE TO RELATED APPLICATION

This application claims the benefit of Korean Patent Application No. 10-2013-0145005 filed on Nov. 27, 2013, with the Korean Intellectual Property Office, the disclosure of which is incorporated herein by reference.

### BACKGROUND

The present disclosure relates to a power semiconductor device having a low turn-on resistance and generating small noise.

An insulated gate bipolar transistor (IGBT) is a transistor manufactured to have bipolarity by forming a gate using a metal oxide semiconductor (MOS) and forming a p-type collector layer on a rear surface thereof.

Since the development of power metal oxide semiconductor field effect transistors (MOSFETs) in the related art, such transistors have been used in fields requiring high speed switching characteristics.

However, due to structural limitations of MOSFETs, bipolar transistors, thyristors, gate turn-off thyristors (GTOs), and the like, have been used in fields requiring high voltages.

Since IGBTs have characteristics such as a low forward loss and rapid switching speeds, the application of IGBTs to fields that may not be appropriate for the use of existing thyristors, bipolar transistors, MOSFETs, and the like, has increased.

The operational principle of IGBTs will be described hereinafter. In the case in which an IGBT device is turned on, a voltage applied to an anode has a higher level than a voltage applied to a cathode, and when a voltage having a level higher than that of a threshold voltage of the IGBT device is applied to a gate electrode, a polarity of a surface of a p-type body region positioned at a lower end of the gate electrode is inverted, such that an n-type channel is formed.

An electron current injected into adrift region through an n-type channel formed in such a manner induces the injection of a hole current from a high-concentration p-type collector layer positioned in a lower portion of the IGBT device, in a manner similar to that of a base current of a bipolar transistor.

Due to the injection of these minority carriers in a high concentration, a conductivity modulation phenomenon in which conductivity in the drift region is increased by several tens to several hundreds of times occurs.

Unlike MOSFETs, in the case of IGBTs, a resistance component in the drift region may be greatly reduced in size due to the conductivity modulation phenomenon. Therefore, IGBTs may have very high levels of voltage applied thereto.

Various technologies have been developed in order to significantly increase the conductivity modulation phenomenon.

For example, a technology for significantly increasing the conductivity modulation phenomenon using a phenomenon in which holes are accumulated by forming a high concentration n-type semiconductor layer below the p-type body layer exists.

As described above, the high concentration n-type semiconductor layer formed under the body region is called a hole accumulating layer.

In the case in which the hole accumulating layer is formed, an amount of accumulated holes is significantly increased, such that a large conductivity modulation phenomenon occurs. However, the holes accumulated in the hole accumulating layer have an influence on an input signal of a trench gate.

That is, the hole accumulating layer has an influence on the trench gate, such that gate noise may be generated.

Gate noise hinders the stable supply of a current.

Particularly, in the case in which a switching frequency is high, a variation width of the current is significantly increased due to such gate noise.

Therefore, a technology capable of decreasing a turn-on resistance by significantly increasing a conductivity modulation phenomenon while decreasing gate noise has been demanded.

The following Related Art Document (Patent Document 1) relates to a power semiconductor device having a low-resistance shield electrode.

### RELATED ART DOCUMENT

(Patent Document 1) U.S. Pat. No. 8,013,387

### SUMMARY

An aspect of the present disclosure may provide a power semiconductor device having low turn-on resistance and reduced generation of switching noise.

According to an aspect of the present disclosure, a power semiconductor device may include: a first semiconductor layer having a first conductivity type; a second semiconductor layer formed on the first semiconductor layer, having a concentration of impurities higher than that of the first semiconductor layer, and having the first conductivity type; a third semiconductor layer formed on the second semiconductor layer and having a second conductivity type; a fourth semiconductor layer formed in an upper surface of the third semiconductor layer and having the first conductivity type; and trench gates penetrating from the fourth semiconductor layer into a portion of the first semiconductor layer and having gate insulating layers formed on surfaces thereof, wherein the trench gates have a first gate, a second gate, and a third gate sequentially formed from a lower portion thereof, the first gate, the second gate, and the third gate being insulated from each other by gate insulating films.

The first gate may be formed in a position corresponding to a height of the third semiconductor layer, the second gate may be formed in a position corresponding to a height of the second semiconductor layer, and the third gate may be formed in a position corresponding to a height of the first semiconductor layer.

Voltages applied to the first gate, the second gate, and the third gate at the time of a turn-on operation of the power semiconductor device may be different from each other.

A voltage applied to the second gate at the time of a turn-on operation of the power semiconductor device may be lower than a voltage applied to the third gate at the time of the turn-on operation of the power semiconductor device.

A voltage applied to the second gate at the time of a turn-on operation of the power semiconductor device may be lower than a voltage applied to the first gate at the time of the turn-on operation of the power semiconductor device.

The power semiconductor device may further include a first gate metal layer, a second gate metal layer, and a third gate metal layer electrically connected to the first gate, the second gate, and the third gate, respectively, and formed on the first semiconductor layer.

The first gate metal layer, the second gate metal layer, and the third gate metal layer may be electrically insulated from each other.

According to another aspect of the present disclosure, a power semiconductor device may include: a trench gate lengthily formed on one direction and extended from an active region in which a current flows at the time of a turn-on operation of the power semiconductor device to a termination region; a metal emitter layer formed on the active region; and a first gate metal layer, a second gate metal layer, and a third gate metal layer formed on the termination region.

The trench gate may have a first gate, a second gate, and a third gate sequentially formed from a lower portion thereof, wherein the first gate, the second gate, and the third gate are insulated from each other by gate insulating films.

The first gate, the second gate, and the third gate may be electrically connected to the first gate metal layer, the second gate metal layer, and the third gate metal layer, respectively.

The power semiconductor device may further include insulating films formed between the first gate metal layer, the second gate metal layer, and the third gate metal layer, respectively.

### BRIEF DESCRIPTION OF DRAWINGS

The above and other aspects, features and other advantages of the present disclosure will be more clearly understood from the following detailed description taken in conjunction with the accompanying drawings, in which:

FIG. 1 is a schematic perspective view of a power semiconductor device according to an exemplary embodiment of the present disclosure;

FIG. 2 is a schematic cross-sectional view illustrating flows of electrons and holes at the time of a turn-on operation of the power semiconductor device according to an exemplary embodiment of the present disclosure; and

FIG. 3 is a schematic side view of the power semiconductor device according to an exemplary embodiment of the present disclosure.

### DETAILED DESCRIPTION

Hereinafter, embodiments of the present disclosure will be described in detail with reference to the accompanying drawings. The disclosure may, however, be embodied in many different forms and should not be construed as being limited to the embodiments set forth herein. Rather, these embodiments are provided so that this disclosure will be thorough and complete, and will fully convey the scope of the disclosure to those skilled in the art. In the drawings, the shapes and dimensions of elements may be exaggerated for clarity, and the same reference numerals will be used throughout to designate the same or like elements.

In the accompanying drawings, x, y, and z directions refer to a width direction, a length direction, and a height direction, respectively.

A power switch may be implemented by any one of a power metal oxide semiconductor field effect transistor (MOSFET), an insulated gate bipolar transistor (IGBT), a thyristor, and devices similar to the above-mentioned devices. Most of new technologies disclosed herein will be described based on the IGBT. However, several exemplary embodiments of the present disclosure disclosed herein are not limited to the IGBT, but may also be applied to other types of power switch technologies including a power MOSFET and several types of thyristors in addition to a diode. Further, several exemplary embodiments of the present disclosure will be described as including specific p-type and n-type regions. However, conductivity types of several regions disclosed herein may be similarly applied to devices having conductivity types opposite thereto.

In addition, an n-type or a p-type used herein may be defined as a first conductivity type or a second conductivity type. Meanwhile, the first and second conductivity types mean different conductivity types.

Further, generally, ‘+’ means the state in which a region is heavily doped and ‘−’ means the state that a region is lightly doped.

Hereinafter, although the first conductivity type will be called an n-type and the second conductivity type will be called a p-type in order to make a description clear, the present disclosure is not limited thereto.

In addition, although a first semiconductor layer will be called a drift layer, a second semiconductor layer will be called a hole accumulating layer, a third semiconductor layer will be called a body layer, and a fourth semiconductor layer will be called an emitter layer will be described, the present disclosure is not limited thereto.

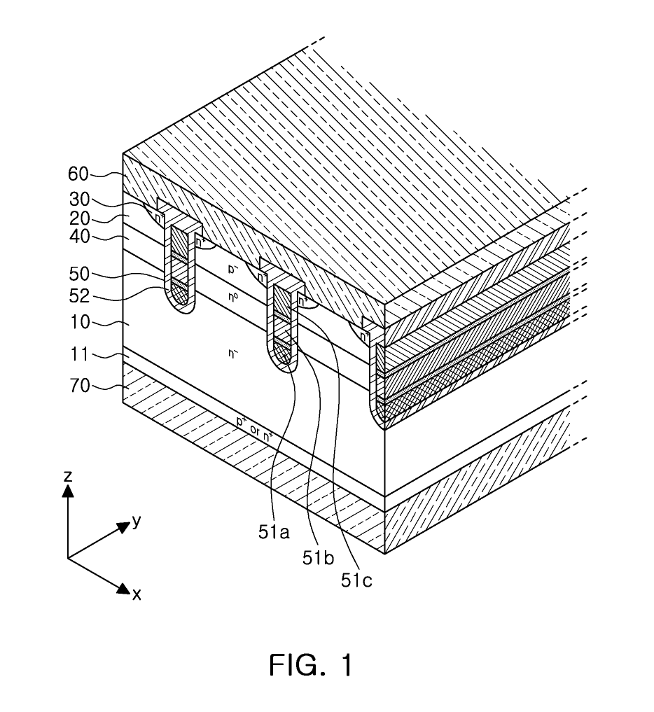

FIG. 1 is a schematic perspective view of a power semiconductor device according to an exemplary embodiment of the present disclosure.

Hereinafter, a structure of the power semiconductor device according to an exemplary embodiment of the present disclosure will be described with reference to FIG. 1.

The power semiconductor device according to an exemplary embodiment of the present disclosure may include a drift layer 10 having a first conductivity type; a hole accumulating layer 40 formed on the drift layer 10 and having the first conductivity type; a body layer 20 formed on the hole accumulating layer 40 and having a second conductivity type; an emitter layer 30 formed in an upper surface of the body layer 20 having the first conductivity type; and trench gates 50 penetrating through the emitter layer 30, the body layer 20, and the hole accumulating layer 40, and having a gate insulating layer 52 formed on a surface thereof, wherein the trench gate 50 has a first gate 51a, a second gate 51b, and a third gate 51c sequentially formed from a lower portion thereof, the first gate 51a, the second gate 51b, and the third gate 51c being insulated from each other by gate insulating films.

In detail, the first gate 51a may be formed in a position corresponding to a height of the body layer 20, the second gate 51b may be formed in a position corresponding to a height of the hole accumulating layer 40, and the third gate 51c may be formed in a position corresponding to a height of the drift layer 10.

The first conductivity type may be an n-type, and the second conductivity type may be a p-type.

The drift layer 10 may have low-concentration n-type impurities in order to maintain a blocking voltage of the power semiconductor device.

The drift layer 10 may have the p-type body layer 20 formed thereon.

The body layer 20 may be continuously formed in a stripe shape in the length direction on one surface of the drift layer 10.

In addition, the body layer 20 may have a plurality of regions.

The body layer 20 may have n+ type emitter layers 30 formed on portions of the upper surface thereof.

In addition, the number of emitter layers 30 may be plural.

Further, the emitter layers 30 may be discretely formed on the surface of the body layer 20.

The body layer 20 and the emitter layer 30 may have a metal emitter layer 60 formed on exposed upper surfaces thereof.

The drift layer 10 may have a collector layer 11 formed therebelow.

A conductivity type of the collector layer 11 may be a p+ type or an n+ type.

The collector layer 11 may have a collector metal layer 70 formed therebelow.

In the case in which a conductivity type of the collector layer 11 is an n+ type, the power semiconductor device according to an exemplary embodiment of the present disclosure may be operated as a MOSFET.

In the case in which a conductivity type of the collector layer 11 is a p+ type, the power semiconductor device according to an exemplary embodiment of the present disclosure may be operated as an IGBT.

In the IGBT, which is the power semiconductor device, the conductivity type of the collector layer 11 is the p-type, such that the collector layer 11 may inject holes into the IGBT in the case in which the IGBT is turned on.

Due to the injection of the holes at a high concentration, a conductivity modulation phenomenon that conductivity in the drift layer 10 is increased several ten to several hundred times may occur.

In order to significantly increase the conductivity modulation phenomenon, the hole accumulating layer 40 having the first conductivity type may be formed on the drift layer 10.

A conductivity type of the hole accumulating layer 40 may be the same as that of the drift layer 10, but a concentration of impurities of the hole accumulating layer may be very higher than that of the drift layer 10.

In detail, the conductivity type of the hole accumulating layer 40 may be an n+ type.

Since the hole accumulating layer 40 has high-concentration n-type impurities, the holes injected from the collector layer 11 may be accumulated in the hole accumulating layer 40.

Therefore, the holes may be accumulated at a high concentration below the body layer 20, such that the conductivity modulation phenomenon may be significantly increased.

However, when the holes are excessively accumulated in the hole accumulating layer 40, a voltage applied to the trench gate 50 may be affected by charges of these holes.

That is, the voltage applied to the trench gate 50 is fluctuated by the holes accumulated in the hole accumulating layer 40, such that a noise may be generated in the case which the power semiconductor device performs a switching operation.

Therefore, according to the related art, there was a limitation in increasing a concentration of first conductivity type (n-type) impurities of the hole accumulating layer 40 to a predetermined value or more.

The trench gate 50 may penetrate the emitting layer 30, the body layer 20, and the hole accumulating layer 40 in the depth direction and may lead to an inner portion of the drift layer 10.

The trench gate 50 may have a gate insulating layer 52 formed on a surface on which it contacts the emitter layer 30, the body layer 20, the hole accumulating layer 40, and the drift layer 10.

The gate insulating layer 52 may be formed of a silicon oxide.

The trench gate 50 may have a conductive material filled therein.

The conductive material may be a polysilicon, but is not limited thereto.

The trench gate 50 may include the first gate 51a, the second gate 51b, and the third gate 51c sequentially formed from the lower portion thereof depending on a kind of regions adjacent thereto.

Generally, required gate voltages may be different from each other depending on heights of the body layer 20, the hole accumulating layer 40, and the drift layer 10.

In the power semiconductor device according to an exemplary embodiment of the present disclosure, voltages applied to the first gate 51a, the second gate 51b, and the third gate 51c may be different from each other.

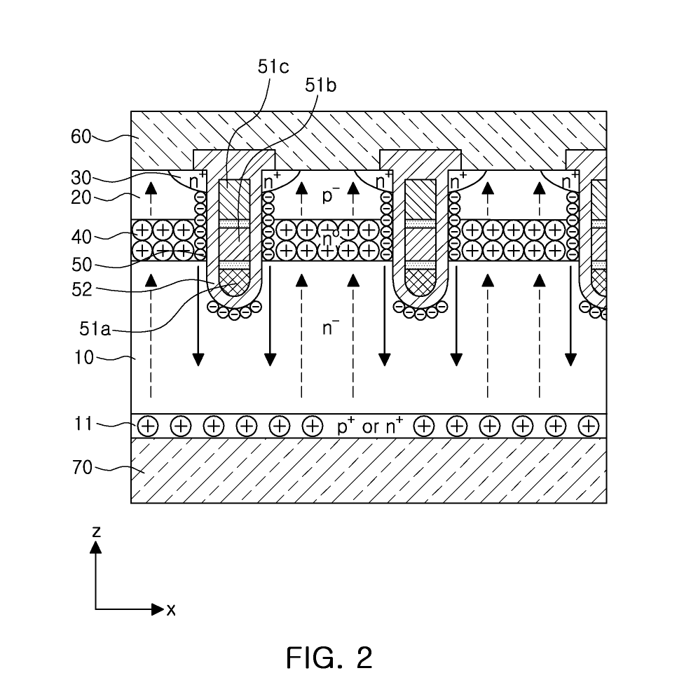

Hereinafter, gate voltages required in the respective layers will be described with reference to FIG. 2.

FIG. 2 is a schematic cross-sectional view illustrating flows of electrons and holes at the time of a turn-on operation of the power semiconductor device according to an exemplary embodiment of the present disclosure.

The body layer 20 may have a channel formed therein at the time of a turn-on operation of the power semiconductor device.

A positive voltage may be applied to the trench gate at the time of the turn-on operation of the power semiconductor device.

Therefore, as illustrated in FIG. 2, electrons may be pulled to a surface of the trench gate 50 by a positive electric field formed by the positive voltage, and a conductive channel may be formed in the body layer 20, such that a current may flow between an emitter and a collector.

The conductive channel may be in association with a turn-on voltage Vth, and the body layer 20 may be in close association with a blocking voltage of the power semiconductor device.

Since the body layer 20 has an influence on several characteristics of the power semiconductor device, a voltage applied to the third gate 51c needs to be controlled in consideration of this feature.

The hole accumulating layer 40 may be formed in order to significantly increase the conductivity modulation phenomenon of the power semiconductor device.

That is, since the hole accumulating layer 40 is formed by injecting n-type impurities at a high concentration, the holes may be accumulated in the hole accumulating layer 40, as illustrated in FIG. 2.

Since the holes have positive charges, the holes accumulated in the hole accumulating layer 40 may generate a positive electric field.

The electric field generated by the holes may have an influence on the second gate 51b.

This will be described in detail.

When a large number of holes having the positive charges are accumulated in the hole accumulating layer 40, a strong positive electric field may be generated by the holes accumulated in the hole accumulating layer 40.

When a positive voltage is applied to the second gate 51b, holes having positive charges may be generated in the second gate 51b. The holes generated in the second gate 51b may be pushed to the vicinity by the positive electric field generated by the holes accumulated in the hole accumulating layer 40.

That is, since the holes generated in the second gate 51b are pushed to the first gate 51a, a concentration of the holes in the first gate 51a may be increased as compared with the related art.

Therefore, the first gate 51a may have a strong positive electric field due to the increased concentration of the holes and may pull more electrons to the surface of the trench gate 50 corresponding to the height thereof.

Therefore, the voltage Vth may be increased, and a wide channel may be formed, such that a large amount of current may flow.

The above-mentioned phenomenon is repeated, such that the voltage applied to the trench gate 50 is fluctuated and a current waveform is also fluctuated, thereby generating a noise.

Therefore, the voltage applied to the second gate 51b is decreased, whereby the generation of the noise in the second gate 51b may be prevented.

In addition, since the holes are moved at a speed very slower than that of the electrons, they may not rapidly disappear in the case in which the power semiconductor device is switched into a turn-off operation.

Therefore, even in the case in which the power semiconductor device is switched into the turn-off operation, the holes accumulated in the hole accumulating layer 40 may still have an influence on the second gate 51b.

Therefore, when the power semiconductor device is switched into the turn-off operation, the voltage applied to the second gate 51b is fluctuated by the holes accumulated in the hole accumulating layer 40, such that a switching noise may be generated.

In order to decrease the switching noise, the voltage applied to the second gate 51b may be lower than a voltage applied to the first gate 51a or the third gate 51c.

The voltage applied to the second gate 51b is low, such that a phenomenon that the second gate 51b is affected by the electric field generated by the holes accumulated in the hole accumulating layer 40 may be decreased.

That is, since the voltage applied to the second gate 51b is low, even in the case in which the holes accumulated in the hole accumulating layer 40 has an influence on the second gate 51b, the voltage applied to the second gate 51b may react insensitively to the electric field generated by the holes accumulated in the hole accumulating layer 40.

Since the voltage applied to the second gate 51b reacts insensitively to the electric field generated by the holes accumulated in the hole accumulating layer 40, the switching noise may be significantly decreased.

A voltage applied to the first gate 51a formed at the portion corresponding to the height of the drift layer 10 may be higher than the voltage applied to the second gate 51b.

Therefore, as illustrated in FIG. 2, in the case in which the power semiconductor device is turned on, electrons may be pulled in the vicinity of the first gate 51a.

That is, more electrodes may be pulled to the first gate 51a, such that the electrons may not be scattered.

Since the electrons are not scattered, an introduction resistance of the electrons may be decreased, such that conduction loss of the power semiconductor device may be decreased.

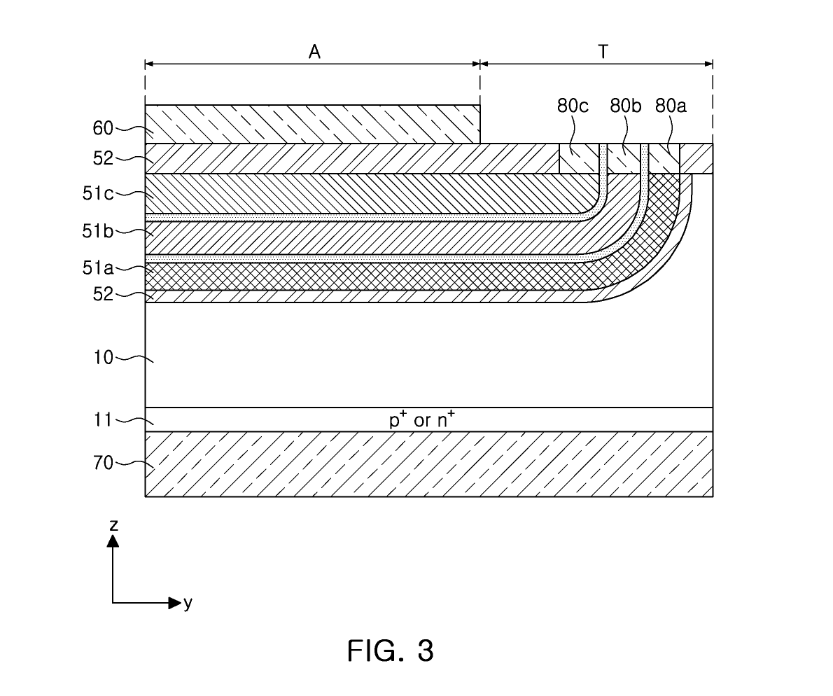

FIG. 3 is a schematic side view of the power semiconductor device according to an exemplary embodiment of the present disclosure.

A configuration of the power semiconductor device according to an exemplary embodiment of the present disclosure will be described with reference to FIG. 3. The power semiconductor device according to an exemplary embodiment of the present disclosure may include: a trench gate lengthily formed on one direction and extended from an active region A in which a current flows at the time of a turn-on operation of the power semiconductor device to a termination region T; a metal emitter layer 60 formed on the active region A; and a first gate metal layer 80a, a second gate metal layer 80b, and a third gate metal layer 80c formed on the termination region T.

The first gate 51a, the second gate 51b, and the third gate 51c may be electrically connected to the first gate metal layer 80a, the second gate metal layer 80b, and the third gate metal layer 80c, respectively.

The first gate metal layer 80a, the second gate metal layer 80b, and the third gate metal layer 80c may have insulating films positioned therebetween, respectively, such that they may be insulated from each other.

Therefore, in the power semiconductor device according to an exemplary embodiment of the present disclosure, since different voltages may be applied to the first gate metal layer 80a, the second gate metal layer 80b, and the third gate metal layer 80c, respectively, different voltages may be applied to the first gate 51a, the second gate 51b, and the third gate 51c, respectively.

Therefore, states such as a noise, a current density, and the like, of the power semiconductor device are confirmed in real time, whereby voltages applied to the first gate metal layer 80a, the second gate metal layer 80b, and the third gate metal layer 80c may be appropriately controlled.

For example, in the case in which a surrounding environment such as a temperature is changed, information is received from an apparatus of measuring the change, whereby the voltages applied to the first gate metal layer 80a, the second gate metal layer 80b, and the third gate metal layer 80c may be appropriately controlled.

Therefore, performance required in the power semiconductor device may be finely controlled, if necessary.

As set forth above, according to exemplary embodiment of the present disclosure, voltages or currents applied to inner portions of the trench gate may be different from each other depending on layers or regions contacting the trench gate, the trench gate may make electric fields having an influence on the respective layer or the respective region different from each other.

When the first gate, the second gate, and the third gate are formed depending on heights from the lower portion of the trench gate, the voltage applied to the second gate formed at the portion corresponding to the height of the hole accumulating layer is lower than the voltage applied to the first gate or the third gate, such that the fluctuation of the gate voltage due to the holes accumulated in the hole accumulating layer may be prevented.

The fluctuation of the gate voltage is prevented, whereby the generation of the switching noise in the power semiconductor device may be significantly decreased.

Further, when the voltage applied to the third gate is the highest and a positive voltage is applied to the trench gate, the electrons are pulled to the surface of the gate insulating layer of the third gate, such that the electrons may not be scattered.

Since the electrons are not scattered, an introduction resistance of the electrons may be decreased, such that conduction loss of the power semiconductor device may be decreased.

While exemplary embodiments have been shown and described above, it will be apparent to those skilled in the art that modifications and variations could be made without departing from the spirit and scope of the present disclosure as defined by the appended claims.

What is claimed is:

1. A power semiconductor device comprising:
a first semiconductor layer of first conductivity type;
a second semiconductor layer of the first conductivity type disposed on the first semiconductor layer, and having a concentration of impurities higher than that of the first semiconductor layer;
a third semiconductor layer of second conductivity type disposed on the second semiconductor layer;
a fourth semiconductor layer of the first conductivity type disposed in an upper surface of the third semiconductor layer; and
trench gates penetrating from the fourth semiconductor layer into a portion of the first semiconductor layer and having gate insulating layers disposed on surfaces thereof,
wherein the trench gates have a first gate, a second gate, and a third gate sequentially disposed from a lower portion thereof,
the first gate, the second gate, and the third gate being insulated from each other by gate insulating films.

2. The power semiconductor device of claim 1, wherein the first gate is formed in a position corresponding to a height of the third semiconductor layer,
the second gate is formed in a position corresponding to a height of the second semiconductor layer, and
the third gate is formed in a position corresponding to a height of the first semiconductor layer.

3. The power semiconductor device of claim 1, wherein voltages applied to the first gate, the second gate, and the third gate at the time of a turn-on operation of the power semiconductor device are different from each other.

4. The power semiconductor device of claim 1, wherein a voltage applied to the second gate at the time of a turn-on operation of the power semiconductor device is lower than a voltage applied to the third gate at the time of the turn-on operation of the power semiconductor device.

5. The power semiconductor device of claim 1, wherein a voltage applied to the second gate at the time of a turn-on operation of the power semiconductor device is lower than a voltage applied to the first gate at the time of the turn-on operation of the power semiconductor device.

6. The power semiconductor device of claim 1, further comprising a first gate metal layer, a second gate metal layer, and a third gate metal layer electrically connected to the first gate, the second gate, and the third gate, respectively, and formed on the first semiconductor layer.

7. The power semiconductor device of claim 6, wherein the first gate metal layer, the second gate metal layer, and the third gate metal layer are electrically insulated from each other.

8. A power semiconductor device comprising:
a trench gate lengthily formed on one direction and extended from an active region in which a current flows at the time of a turn-on operation of the power semiconductor device to a termination region;
a metal emitter layer formed on the active region; and
a first gate metal layer, a second gate metal layer, and a third gate metal layer formed on the termination region.

9. The power semiconductor device of claim 8, wherein the trench gates have a first gate, a second gate, and a third gate sequentially formed from a lower portion thereof,
the first gate, the second gate, and the third gate being insulated from each other by gate insulating films.

10. The power semiconductor device of claim 9, wherein the first gate, the second gate, and the third gate are electrically connected to the first gate metal layer, the second gate metal layer, and the third gate metal layer, respectively.

11. The power semiconductor device of claim 8, further comprising insulating films formed between the first gate metal layer, the second gate metal layer, and the third gate metal layer, respectively.
